(19) United States
(12) Patent Application Publication
(10) Pub. No.: US 2004/0182309 A1
(43) Pub. Date: Sep. 23, 2004

(54) Low temperature deposition of silicon based thin films by single-wafer hot-wall rapid thermal chemical vapor deposition

(76) Inventors: Yoshihide Senzaki, Aptos, CA (US); Carl Anthony Barelli, Boulder Creek, CA (US); Dana Teasdale, Santa Cruz, CA (US); Joseph Charles Sisson, Watsonville, CA (US)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/656,628

(22) Filed: Sep. 5, 2003

Related U.S. Application Data
(60) Provisional application No. 60/408,709, filed on Sep. 5, 2002.

(51) Int. Cl. C30B 23/00; C30B 25/00; C30B 28/12; C30B 28/14

(52) U.S. Cl. 117/84; 117/89

(57) ABSTRACT

The present invention provides a single-wafer hot-wall RTCVD system and method capable of achieving high deposition rates, preferably of up to and over 1000 Å/min, to deposit silicon nitride films or layers (Si₃N₄) using reactants including but not limited to Si₂H₆ with NH₃ at a low temperatures of up to approximately 550° C.

### CROSS REFERENCE TO RELATED APPLICATIONS

This application claims the benefit of and priority to the U.S. Provisional Application No. 60/408,709 filed Sep. 5, 2002, entitled “Low Temperature Deposition of Silicon Based Thin Films by Single Wafer Hot-Wall Rapid Thermal Chemical Vapor Deposition”, the disclosure of which is herein incorporated by reference in its entirety.

### FIELD OF THE INVENTION

The present invention relates generally to systems and methods for processing of semiconductors. More specifically, the present invention relates to a system and method for deposition of silicon based films at low temperatures using single wafer hot-wall thermal chemical vapor deposition.

### BACKGROUND OF THE INVENTION

Low thermal budget processing of silicon-based dielectrics is becoming increasingly important in future IC device fabrication. For example, the self-aligned metal silicide process requires a low temperature deposition of silicon nitride sidewall spacers.

Conventional low pressure chemical vapor deposition (LPCVD) processes have been performed using a hot wall batch furnace with dichlorosilane. Such a system is comprised of a large cylinder in which up to 150 wafers can be loaded. The temperature is slowly ramped up to its setpoint before gases are introduced to initiate deposition. Typical cycle times for this technique are on the order of 6 hours. Silane is not commonly used in batch furnace processes due to the difficulty in achieving thickness uniformity control.

Alternatively, single-wafer rapid thermal chemical vapor deposition (RTCVD) techniques in a cold wall reactor have been used to rapidly deposit films under LPCVD conditions using silane as a precursor or reactant. These systems use lamp-based technology to heat the wafers and are sensitive in wafer temperature control to wafer backside emissivity. Dichlorosilane is not suitable for cold-wall system reactor due to condensation of NH₄Cl solid byproduct. Thus, both conventional techniques suffer from limitations, and improved systems and methods for deposition of silicon based films are highly desirable.

More recently, an improvement has been made using an RTCVD technique in a hot-wall reactor. This method is described in commonly assigned U.S. application Ser. No. 10/106,677 filed Mar. 25, 2002, entitled “System And Method For Improved Thin Dielectric Films” the disclosure of which is hereby incorporated by reference in its entirety. While this technique provides an advantage, the process is carried out at high temperatures generally up to approximately 900° C. Lower temperatures are more desirable, and thus there remains a need for further developments in the industry.

### SUMMARY OF THE INVENTION

The present invention provides a single-wafer hot-wall RTCVD system and method capable of achieving high deposition rates, to deposit silicon nitride films or layers (Si₃N₄) using certain precursors or reactants at low temperatures of up to approximately 550° C. Despite such a high deposition rate, the resulting films produced by the present invention show unexpectedly beneficial thickness uniformity and step coverage properties.

In one embodiment a method of depositing a silicon based film on a wafer is provided characterized in that at least one silicon containing precursor and at least one chemical precursor are introduced into a hot-wall thermal chemical vapor deposition chamber housing a wafer, and wherein the precursors react to form a silicon based film on the wafer at a deposition rate of approximately 100 Å/min. or greater.

In another embodiment, a method of depositing a silicon based film on a wafer in a hot-wall thermal chemical vapor deposition chamber is provided wherein the wafer is heated to a temperature of up to approximately 550° C.; with the pressure in the chamber being in the range of approximately 10 to 500 Torr. At least one silicon containing precursor is conveyed to the chamber and is comprised of any one of, or combination of SiH₄, SiCl₂H₂, Si₂H₆, Si₂Cl₆, SiCl₃H, or SiCl₄, and at least one nitrogen containing precursor comprised of any one of or combination of NH₃, alkyl amine, hydrazine, alkylhydrazine, alkyl amide, alkyl imide or atomic nitrogen is conveyed to the chamber. The precursors react and deposit a silicon based film on the wafer at a deposition rate of 1000 Å/minute and greater.

### BRIEF DESCRIPTION OF THE DRAWINGS

The invention will be described in detail in the following description of preferred embodiments with reference to the following figures wherein:

FIG. 1 is a simplified cross sectional schematic view of one example of a rapid thermal chemical vapor deposition system suitable for carrying out the present invention according to one embodiment.

FIG. 2 illustrates a graph of thickness passive data collection or repeatability test (PDC) results for wafers fabricated according to one embodiment of the present invention;

FIG. 3 illustrates a graph of refractive index PDC results for wafers fabricated according to one embodiment of the present invention;

FIG. 4 shows the effect of Si₂H₆ and NH₃ on the deposition rate and refractive index at constant pressure, temperature and nitrogen gas flow rate; and

FIG. 5 is a cross section of a SEM image showing the step coverage achieved with the system and method of the present invention.

### DETAILED DESCRIPTION OF THE INVENTION

The present invention provides a system and method for deposition of silicon based films at low temperatures using a hot-wall, single wafer, rapid thermal chemical vapor deposition (RTCVD) system.

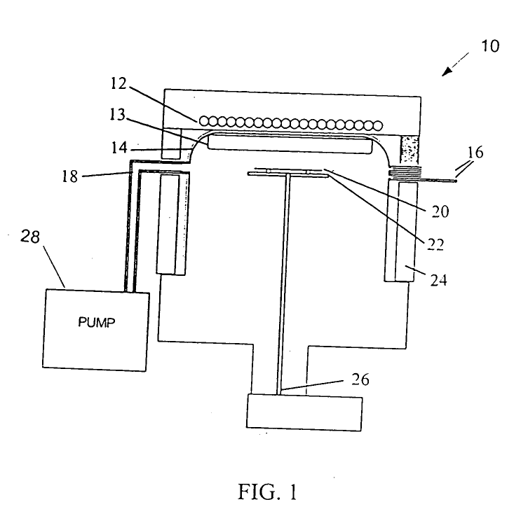

Shown in FIG. 1 is a simplified schematic of the single-wafer hot-wall rapid thermal chemical vapor deposition (RTCVD) system or reactor which may be used to carry out the method of the present invention. While one example of an RTCVD system is shown in FIG. 1, other RTCVD systems may be used. In general, the exemplary hot-wall RTP reactor 10 comprises a chamber 14 into which a single substrate 20 is loaded. The wall of the chamber 14 is preferably made of quartz. A plurality of heating elements 12 are provided adjacent to the upper end of the chamber 14. Suitable heating elements include resistive heating elements coupled with a power source controlled by a computer (not shown). In one embodiment an isothermal plate 13, preferably made of quartz, is disposed inside and adjacent to the upper end of the chamber 14. Alternatively, the isothermal plate 13 may be positioned outside of the chamber 14, such as adjacent to the heating elements 12. The heating elements 12 and isothermal plate 13 serve as heating sources for the use of the RTP reactor 10. The isothermal plate 13 can be placed in the chamber 14 or on the top of chamber 14. The isothermal plate 13 receives heat rays radiated from the heating elements 12 and radiates secondary heat rays into the chamber 14. The isothermal plate 13 can produce more uniform thermal distribution on the surface of the substrate 20 and is thus preferred but is not required.

The hot-wall RTP reactor 10 further comprises one or more insulation sidewalls 24 adjacent to the sidewall of chamber 14. Heating means (not shown) may be provided between the insulation sidewalls 24 and the sidewall of the chamber 14 to heat the sidewall of the chamber 14 to achieve a more accurate control over the temperature within the chamber 14.

The single substrate 20 is supported by a platform 22 which is coupled with an elevator 26 for moving the substrate 20 into and out of the chamber 14. One or more gas inlets 16 are disposed at the sidewall of the chamber 14 and connected to one or more gas manifolds (not shown) which convey a gas or a mixture of gases into the chamber 14. The gas concentration and flow rates through each of the gas inlets 16 are selected to produce reactant gas flows and concentration that optimize processing uniformity. An exhaust line 18 is provided at the sidewall of the chamber 14 opposite the gas inlets 16 and connected to a pump 28 for exhausting the chamber 14. While one specific hot-wall RTP reactor has been described, the invention is not limited to this specific design, and other hot-wall RTP reactors may be employed within the teaching of the present invention.

In one embodiment, the present invention provides a method of depositing a silicon based film on a wafer wherein at least one silicon containing precursor and at least one chemical precursor (sometimes collectively referred to as “process gases”) are introduced into a hot-wall thermal CVD chamber housing a wafer. The wafer is heated to a wafer temperature of up to approximately 550° C. The process gases mix and react to form a silicon based film on the wafer.

More specifically, in one example the method is carried out as follows. A wafer is loaded into a lower chamber (not shown) of reactor 10. The wafer is then pushed under vacuum into chamber 14 as shown in FIG. 1, via elevator 26. Energy is applied to the heating elements to heat the wafer. Process gases are then introduced, and the film is deposited on the silicon wafer until a desired thickness has been achieved. After deposition is complete, the wafer is lowered for cooling.

Of particular advantage, the present invention provides high deposition rates at relatively low temperatures. More specifically, the present invention provides for heating the wafer to a temperature of up to approximately 550° C. In another embodiment, the wafer temperature is in the range of approximately 400° C. to 550° C. In yet another embodiment the wafer temperature is in the range of approximately 400° C. to 525° C. The method of the present invention is carried out at a pressure in the range of approximately 10 to 500 Torr, more preferably between 100 and 200 Torr.

Suitable silicon source precursors include both chlorine- and hydride-based silicon sources, such as but not limited to SiH₄, SiCl₂H₂, Si₂H₆, Si₂Cl₆, SiCl₃H, and SiCl₄. In one embodiment of the present invention, the flow rate of such suitable silicon source precursor is conveyed to the chamber is in the range of 10 sccm to 500 sccm.

The present invention includes in particular the use of Si₂H₆ as the precursor for depositing silicon based films such as silicon nitride, silicon oxide, silicon oxynitride, polysilicon, and germanium doped polysilicon.

The silicon source precursor may be conveyed with or without one or more inert gases. Examples of suitable inert gases include, but are not limited to nitrogen, argon, helium, and the like. In one embodiment of the invention, inert gas is conveyed to the chamber at a flow rate in the range of 0 to 20,000 sccm.

In one embodiment the chemical precursor is a nitrogen source. Suitable nitrogen source precursors include any one, or combination, of NH₃, alkyl amine, hydrazine, alkylhydrazine, alkyl amide, alkyl imide, and atomic nitrogen. In one embodiment, such nitrogen source precursors are conveyed to the chamber at a flow rate in the range of 10 to 10,000 sccm.

An oxidant may also be employed. Suitable oxidant sources include any one, or combination, of Ozone, O₂, NO N₂O, H₂O, H₂O₂, and atomic oxygen.

Unlike that found using metal-organic precursors in the prior art, such as bis(t-butylamino)silane (BTBAS), the resulting films prepared by the method of the present invention have no carbon contamination.

The present invention may be employed to fabricate a number of semiconductor device structure, such as, but not limited to: sidewall spacers (Si₃N₄, SiO₂); gate and capacitor dielectrics (Si₃N₄, SiOxNy, ON stack, ONO stack); gate electrodes (polysilicon, Poly Si—Ge); and optical coatings (SiOxNy).

### Experimental

A number of experiments were preformed. The following experimental results are provided for purposes of illustration only, are not intended to limit the invention in any way. Deposition rates of approximately 1000 Å/min were obtained with uniformity <2% 1σ. The refractive index (RI) was also found to be controllable to provide a RI of 2.007±0.003. Listed below in Table 1 are the process parameters and results of the high deposition rate.

TABLE 1
Si₂H₆ process parameters for the
high deposition rate CVD of Si₃N₄.

| | Pump- | | | | Pump- |
|---|---|---|---|---|---|
| Setpoint | down | Initialize | Deposition | Cooling | down |
| Process time [s] | 120 | 120 | Variable | 120 | 60 |
| Si₂H₆ [sccm] | 0 | 0 | 320 | 0 | 0 |
| NH₃ [sccm] | 0 | 6075 | 6075 | 6705 | 0 |
| N₂ [sccm] | 0 | 4675 | 4675 | 4675 | 0 |
| Pressure Setting | 0.010 | 130 | 130 | 130 | 0.010 |
| [Torr] | | | | | |
| Elevator Position | Cooling | Process | Process | Cooling | Cooling |
| Rotator Speed | 0 | 6 | 6 | 6 | 0 |
| [rpm] | | | | | |
| Wafer Temp. | N/A | 550 | 550 | 550 | N/A |
| [° C.] | | | | | |

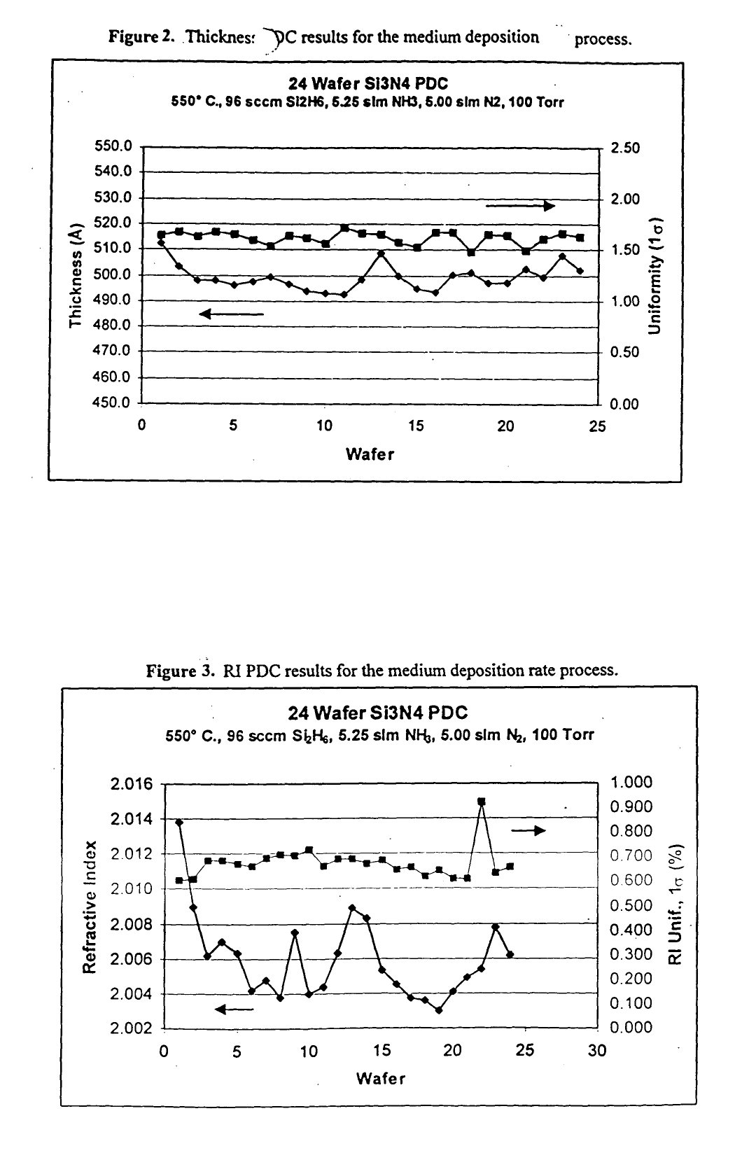

In addition, a medium deposition rate process of approximately 500 Å/min has been created. The parameters for this process are shown in Table 2. A twenty-four wafer PDC was performed using this process and the results are presented in FIG. 2 and FIG. 3.

TABLE 2
Si₂H₆ process parameters for the
medium deposition rate CVD of Si₃N₄.

| | Pump- | | | | Pump- |
|---|---|---|---|---|---|
| Setpoint | down | Initialize | Deposition | Cooling | down |
| Process time [s] | 120 | 120 | Variable | 120 | 60 |
| Si₂H₆ [sccm] | 0 | 0 | 96 | 0 | 0 |
| NH₃ [sccm] | 0 | 5250 | 5250 | 5250 | 0 |
| N₂ [sccm] | 0 | 5005 | 5000 | 5000 | 0 |
| Pressure Setting | 0.010 | 100 | 100 | 100 | 0.010 |
| [Torr] | | | | | |
| Elevator Position | Cooling | Process | Process | Cooling | Cooling |
| Rotator Speed [rpm] | 0 | 6 | 6 | 6 | 0 |
| Wafer Temp.[° C.] | N/A | 550 | 550 | 550 | N/A |

The data from the PDC has been analyzed and is presented below in Table 3. Excellent repeatability was achieved in both thickness and RI.

TABLE 3
Processed data from PDC.

| | Thickness | Thickness | | |
|---|---|---|---|---|
| | (Å) | 1σ (%) | RI Mean | RI 1σ (%) |
| Average | 499.31 | 1.62 | 2.006 | 0.675 |
| Max | 512.18 | 1.71 | 2.014 | 0.926 |
| Min | 492.64 | 1.48 | 2.003 | 0.608 |
| St Dev. | 4.94 | 0.06 | 0.002 | 0.064 |
| WTW | 0.99 | | 0.120 | |
| Unif. (1σ) | | | | |

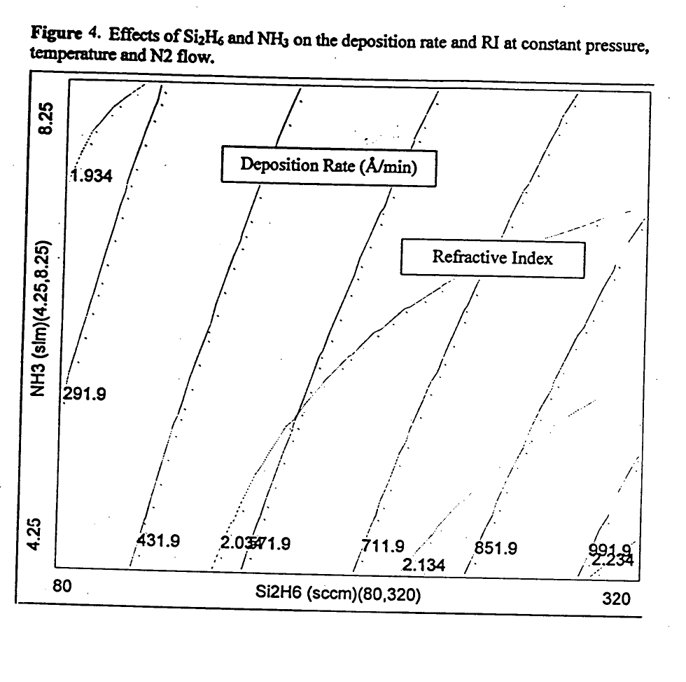

Several experiments were performed to determine the effects of the individual parameters on the results of the process. These relationships are summarized below in Table 4 and are illustrated in FIG. 4. The Si₂H₆ flow was found to be the largest contributor to the deposition rate. This was followed by NH₃ flow. The effects of both variables have been plotted at a constant N₂ flow of 5.0 slm, a pressure of 100 Torr at a wafer temperature of 550° C.

TABLE 4
Effects of process variables on the process performance.
The arrows next to the results represent either an increase
(↑) or decrease (↓) as the primary variable is
increased. Negligible effects are denoted with an ‘X’.

| | Response | | |
|---|---|---|---|
| Variable | Dep. Rate | RI | Unif. |
| ↑ Si₂H₆ | ↑↑ | ↑ | X |
| ↑ NH₃ | ↓ | ↓ | ↓ |
| ↑ N₂ | | X | ↓ |
| ↑ Pressure | ↑ | ↓ | X |
| ↑ Elevator | ↑ | ↑ | ↑ & ↓ |

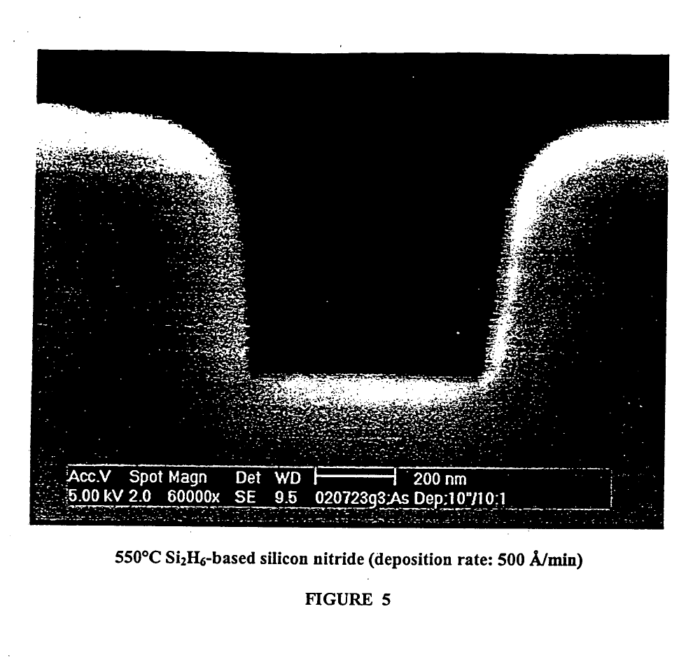

FIG. 5 shows the excellent step coverage achieved by the system and method of the present invention. The film shown in the SEM image is silicon nitride deposited with a Si₂H₆ precursor at a temperature of about 550° C. and at a deposition rate of about 500 Å/min.

Exemplary embodiments have been described with reference to specific configurations. The foregoing description of specific embodiments and examples of the invention have been presented for the purpose of illustration and description, and although the invention has been illustrated by certain of the preceding examples, it is not to be construed as being limited thereby.

What is claimed is:

1. A method of depositing a silicon based film on a wafer characterized in that at least one silicon containing precursor and at least one chemical precursor are introduced into a hot-wall thermal chemical vapor deposition chamber housing a wafer, and wherein the precursors react to form a silicon based film on the wafer at a deposition rate of approximately 1000 Å/min. or greater.

2. The method of claim 1 wherein said method is carried out at a wafer temperature of up to about 550° C.

3. The method of claim 1 wherein said at least one silicon containing precursor is comprised of any one of or combination of SiH₄, SiCl₂H₂, Si₂H₆, Si₂Cl₆, SiCl₃H, or SiCl₄.

4. The method of claim 1 wherein said at least one silicon containing precursor is Si₂H₆ and said at least one chemical precursor is NH₃.

5. The method of claim 1 wherein said at least one chemical precursor is a nitrogen source selected from the group of NH₃, alkyl amine, hydrazine, alkylhydrazine, alkyl amide, alkyl imide, and atomic nitrogen.

6. The method of claim 1 wherein said method is carried out at a pressure in the range of about 10 to 500 Torr.

7. The method of claim 1 wherein said method is carried out at a pressure in the range of about 100 to 130 Torr.

8. The method of claim 1 further comprising introducing an inert gas into the hot wall thermal chamber.

9. The method of claim 1 further comprising introducing an oxidant into the hot wall thermal chamber, and wherein the oxidant is comprised of any one of or combination of ozone, O₂, NO, N₂O, H₂O, H₂O₂ and atomic oxygen.

10. The method of claim 1 wherein the silicon containing precursor is conveyed at a flow rate in the range of 10 sccm to 500 sccm.

11. A method of depositing a silicon based film on a wafer in a hot-wall thermal chemical vapor deposition chamber, comprising the steps of:
heating the wafer to a temperature in the range of 400 to 550° C.;
reacting at least one silicon containing precursor and ate least one nitrogen containing precursor to deposit a silicon based film on the wafer.

12. The method of claim 11 wherein said at least one silicon containing precursor is comprised of any one of, or combination of SiH₄, SiCl₂H₂, Si₂H₆, Si₂Cl₆, SiCl₃H, or SiCl₄.

13. The method of claim 11 wherein said at least one silicon containing precursor is Si₂H₆ and said at least one nitrogen precursor is NH₃.

14. The method of claim 11 wherein said at least one nitrogen precursor is comprised of any one of or combination of NH₃, alkyl amine, hydrazine, alkylhydrazine, alkyl amide, alkyl imide or atomic nitrogen.

15. The method of claim 11 wherein said method is carried out at a pressure in the range of about 10 to 500 Torr.

16. The method of claim 11 further comprising introducing an oxidant into the hot wall thermal chamber, and wherein the oxidant is comprised of any one of or combination of ozone, O₂, NO, N₂O, H₂O, H₂O₂ and atomic oxygen.

17. A method of depositing a silicon based film on a wafer in a hot-wall thermal chemical vapor deposition chamber, comprising the steps of:
heating the wafer to a temperature of up to approximately 550° C.;
establishing the pressure in the chamber in the range of approximately 10 to 500 Torr;
conveying at least one silicon containing precursor comprised of any one of, or combination of SiH₄, SiCl₂H₂, Si₂H₆, Si₂Cl₆, SiCl₃H, or SiCl₄, and at least one nitrogen containing precursor comprised of any one of or combination of NH₃, alkyl amine, hydrazine, alkylhydrazine, alkyl amide, alkyl imide or atomic nitrogen; and
reacting said silicon and nitrogen containing precursors to deposit a silicon based film on the wafer.
